(19) United States
(12) Patent Application Publication
(10) Pub. No.: US 2025/0079790 A1
(43) Pub. Date: Mar. 6, 2025

(54) LASER DIODE AND METHOD FOR PREPARING STACKED HIGH-DENSITY LASER DIODE ARRAY

(71) Applicant: SAE Magnetics (H.K.) Ltd., Hong Kong (CN)

(72) Inventors: Tai Boon LEE, Hong Kong (CN); Seiichi TAKAYAMA, Hong Kong (CN)

(21) Appl. No.: 18/402,159

(22) Filed: Jan. 2, 2024

(30) Foreign Application Priority Data
Sep. 4, 2023 (CN) 202311127269.1

(51) Int. Cl. H01S 5/028; H01S 5/22

(52) U.S. Cl. CPC H01S 5/028; H01S 5/22

(57) ABSTRACT

The present disclosure provides a laser diode and a method for preparing a stacked high-density laser diode array. The laser diode includes a substrate and a stack layer, where the stack layer includes a P-type layer with a ridge strip; the laser diode is provided with a waveguide surface, a light output surface, a reflective surface, and a bottom surface; a top side of the P-type layer forms the waveguide surface, and a bottom side of the substrate forms the bottom surface; the waveguide surface is provided opposite to the bottom surface; the bottom surface is provided with at least one groove; an extension direction of the groove is perpendicular to the ridge strip; and edges of two sides of the waveguide surface, the light output surface, and the reflective surface are all coated.

### CROSS REFERENCE TO RELATED APPLICATIONS

The present application claims the benefit of Chinese Patent Application No. 202311127269.1 filed on Sep. 4, 2023, the contents of which are incorporated herein by reference in their entirety.

### TECHNICAL FIELD

The present disclosure relates to the technical field of laser diode, and in particular to a laser diode having groove(s), and a method for preparing a stacked high-density laser diode array.

### BACKGROUND

The resonant mirror of a laser diode includes a light output surface and a reflective surface opposite the light output surface. The resonant mirror needs to be coated to prevent deterioration of the resonant mirror during operation and change the reflectivity of the resonant mirror, thereby improving the electrical performance of the laser diode.

The coating on the resonant mirror needs to maintain high purity and cleanliness. The existing laser diode has a rectangular structure, and its resonant mirror includes two opposite surfaces that require double-sided coating. In the prior art, the laser diode is clamped by a fixture. After the light output surface of the laser diode is coated, the fixture is flipped over to coat the reflective surface of the laser diode. Specifically, refer to FIG. 1, FIG. 1 is a structural diagram of a fixture in the prior art. As shown in FIG. 1, multiple laser diode bars are arranged in sequence from bottom to top. The bottommost laser diode bar is clamped by a first fixture a1, and the topmost laser diode bar is clamped by a second fixture a2. The left sides of all the laser diode bars are clamped by a third fixture a3, and the right sides of all the laser diode bars are clamped by a fourth fixture a4. A spacer a5 is provided between each two adjacent laser diode bars to separate them. During the preparation process, the directions of the fixtures are first adjusted to orient the light output surfaces of the laser diode bars upwards, such that the light output surfaces of all the laser diode are vacuum-deposited. Then, the directions of the fixtures are adjusted to orient the light output surfaces of the laser diode bars downwards, such that the reflective surfaces of all the laser diodes are vacuum-deposited. In this way, the resonant mirrors of all the laser diode bars are coated.

However, during actual coating, due to the small size of the laser diode product, a large number of spacers are required inside the fixtures, which significantly increases the product processing cost. Besides, due to the influence of the material, the spacer may bend during use, resulting in a non-flat surface between the spacer and the laser diode, which will in turn affect the coating quality. More importantly, due to the presence of the third fixture and the fourth fixture, the left side of the laser diode held by the third fixture cannot be coated, and the right side of the laser diode held by the fourth fixture cannot be coated. The incomplete coating on the left and right sides of the laser diode will seriously affect the electrical performance of the laser diode.

In summary, due to the structural limitation, the existing laser diode product cannot achieve a satisfactory coating effect on the resonant mirror. Therefore, solving the coating problem of the resonant mirror of the laser diode has become an urgent technical problem for those skilled in the art.

### SUMMARY

The present disclosure provides a laser diode and a method for preparing a stacked high-density laser diode array. The present disclosure improves the structure of the laser diode by forming at least one groove on a bottom surface of the laser diode to facilitate coating on edges of two sides of a waveguide surface, on a light output surface, and on a reflective surface, ensuring the electrical performance of the laser diode.

In order to solve the above technical problem, an embodiment of the present disclosure provides a laser diode. The laser diode includes a substrate and a stack layer located on the substrate, where the stack layer includes an N-type layer, an active layer, and a P-type layer with a ridge strip on a surface; and the laser diode is provided with a waveguide surface, a light output surface, a reflective surface, and a bottom surface;
a top side of the P-type layer forms the waveguide surface, and a bottom side of the substrate forms the bottom surface; and the waveguide surface is provided opposite to the bottom surface;
the bottom surface is provided with at least one groove; and an extension direction of the groove is perpendicular to the ridge strip;
the light output surface and the reflective surface are located at two opposite sides of the waveguide surface and perpendicular to the waveguide surface; and
an edge of a side of the waveguide surface connected to the light output surface, an edge of a side of the waveguide surface connected to the reflective surface, the light output surface, and the reflective surface are all coated.

In a preferred solution, the bottom surface is provided with a first groove and a second groove; the first groove is located at an end of the bottom surface connected to the reflective surface; the second groove is located at an end of the bottom surface connected to the light output surface; and the first groove and the second groove form a downwardly extending strip protrusion on the bottom surface.

In a preferred solution, the strip protrusion has a height of 0.5-20 μm.

In a preferred solution, the first groove has a width of 5-50 μm, and the second groove has a width of 5-50 μm.

In a preferred solution, a difference between a coating width on the edge of the side of the waveguide surface connected to the light output surface and the width of the second groove is greater than 2 μm.

Another embodiment of the present disclosure provides a method for coating a resonant mirror of a laser diode array, suitable for the laser diode as described above. The method for coating a resonant mirror of a laser diode array includes the following steps:
arranging at least two laser diodes to form a laser diode bar, wherein the waveguide surface of each of the laser diodes is oriented in a same direction and located in a same plane, the bottom surface of each of the laser diodes is oriented in a same direction and located in a same plane, the light output surface of each of the laser diodes is oriented in a same direction and located in a same plane, and the reflective surface of each of the laser diodes is oriented in a same direction and located in a same plane;
stacking at least two laser diode bars to form a laser diode array, where each of the laser diode bars is in contact with at least one other laser diode bar; the light output surface of each of the laser diodes in each of the laser diode bars is oriented in a same direction and located in a same plane, and the reflective surface of each of the laser diodes in each of the laser diode bars is oriented in a same direction and located in a same plane; and
applying an anti-reflective coating on the light output surface of each of the laser diodes in the laser diode bars stacked; applying a reflective coating on the reflective surface of each of the laser diodes in the laser diode bars stacked; applying a coating on the edge of the side of the waveguide surface connected to the light output surface of each of the laser diodes in the laser diode bars stacked; and applying a coating on the edge of the side of the waveguide surface connected to the reflective surface of each of the laser diodes in the laser diode bars stacked.

Yet another embodiment of the present disclosure provides a method for preparing a stacked high-density laser diode array, where the laser diode array is formed by stacking laser diode bars; each of the laser diode bars includes at least two laser diodes as described above; and the method for preparing a stacked high-density laser diode array includes the following steps:
forming an epitaxial layer on a semiconductor chip, where the epitaxial layer includes a quantum well;
depositing a first metallized layer on a first surface of the semiconductor chip and a second metallized layer on a second surface of the semiconductor chip opposite the first surface;
applying a solder layer on the first metallized layer;
applying an anti-corrosion agent coating on the second metallized layer, and performing baking, exposure, development, dry etching, and demolding in sequence to form multiple grooves on the second surface of the semiconductor chip;
cutting the semiconductor chip into multiple laser diode bars;
stacking the multiple laser diode bars to form the laser diode array, where the waveguide surface of each of the laser diodes in each of the laser diode bars is oriented in a same direction and located in a same plane; the bottom surface of each of the laser diodes in each of the laser diode bars is oriented in a same direction, located in a same plane, and provided with at least one groove; the light output surface of each of the laser diodes in each of the laser diode bars is oriented in a same direction and located in a same plane; and the reflective surface of each of the laser diodes in each of the laser diode bars is oriented in a same direction and located in a same plane; and
putting the laser diode array into a vacuum chamber for vacuum sputtering, such that an anti-reflective coating is applied on the light output surface of each of the laser diodes in the laser diode bars, a reflective coating is applied on the reflective surface of each of the laser diodes in the laser diode bars, a coating is applied on the edge of the side of the waveguide surface connected to the light output surface of each of the laser diodes in the laser diode bars, and a coating is applied on the edge of the side of the waveguide surface connected to the reflective surface of each of the laser diodes in the laser diode bars.

Compared to the prior art, the embodiments of the present disclosure achieve most if not all of the following beneficial effects. The structure of the laser diode is improved by forming at least one groove on the bottom surface of the laser diode. Through the groove, when the laser diode is coated, the coating on the light output surface can spread to the edge of the side of the waveguide surface connected to the light output surface, such that a portion of one end of the waveguide surface is coated. In addition, through the groove, when the laser diode is coated, the coating on the reflective surface can spread to the edge of the side of the waveguide surface connected to the reflective surface, such that a portion of the other end of the waveguide surface is coated. Finally, parts of the formed laser diode product, including the light output surface, the reflective surface, and a portion of the waveguide surface are all coated. Therefore, it is easy to coat the edges of the two sides of the waveguide surface, the light output surface, and the reflective surface, thereby ensuring the electrical performance of the laser diode.

### BRIEF DESCRIPTION OF THE DRAWINGS

FIG. 1 is a structural diagram of a fixture in the prior art;

FIG. 2a is a structural diagram of a laser diode with one groove according to Embodiment 1 of the present disclosure;

FIG. 2b is a structural diagram of a laser diode with two grooves according to Embodiment 1 of the present disclosure;

FIG. 3 is a cross-sectional view of the laser diode with two grooves according to the present disclosure;

FIG. 4 is a side view of a coated laser diode according to an embodiment of the present disclosure;

FIG. 5a is a structural diagram of a laser diode bar according to Embodiment 2 of the present disclosure;

FIG. 5b is a structural diagram of a bottom surface of the laser diode bar according to Embodiment 2 of the present disclosure;

FIG. 6 is a flowchart and cross-sectional view of processing a semiconductor chip to form grooves according to the present disclosure;

FIG. 7 is a schematic diagram of a processed semiconductor chip according to the present disclosure;

FIG. 8 is a schematic diagram of cutting the semiconductor chip according to the present disclosure;

FIG. 9a is a side sectional view of a fixture for fixing a laser diode bar according to Embodiment 5 of the present disclosure;

FIG. 9b is a top view of the fixture for fixing a laser diode bar according to Embodiment 5 of the present disclosure;

FIG. 9c is an enlarged view of X of the fixture for fixing a laser diode bar according to Embodiment 5 of the present disclosure;

FIG. 10a is a partial cross-sectional view of the fixture with support bars according to Embodiment 5 of the present disclosure; and

FIG. 10b is a partial top view of the fixture with the support bars according to Embodiment 5 of the present disclosure.

### REFERENCE NUMERALS

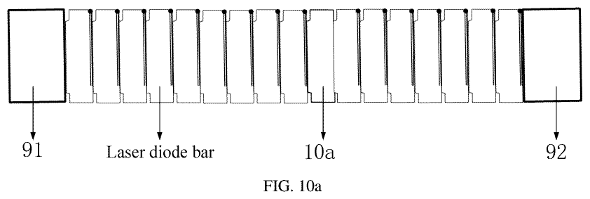

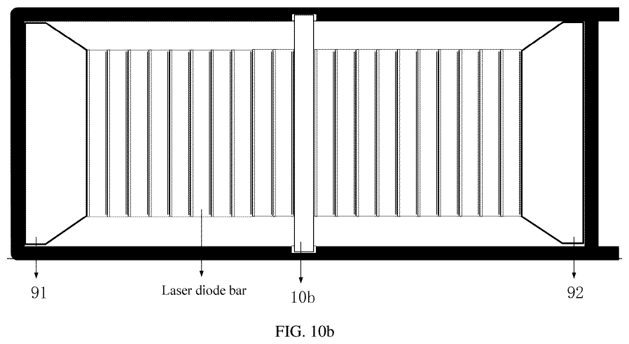

a1. first fixture; a2. second fixture; a3. third fixture; a4. fourth fixture; a5. spacer; 1. substrate; 2. stack layer; 21. N-type layer; 22. active layer; 23. P-type layer; 24. ridge strip; 3. waveguide surface; 4. light output surface; 5. reflective surface; 6. bottom surface; 61. groove; 62. first groove; 63. second groove; 7. base; 8. stage; 91. first stop; 92. second stop; 10a. support bar shown in FIG. 10a; 10b. support bar shown in FIG. 10b; M. strip protrusion; D. extension height of strip protrusion; L1. width of first groove; L2. width of second groove; N1. edge of waveguide surface; N2. edge of waveguide surface; J. first electrode surface; K. second electrode surface; P. first resonant mirror; Q. second resonant mirror; C. holding space; S1. difference between coating width on the edge of a side of the waveguide surface 3 connected to the reflective surface 5 and width L1 of the first groove 62; and S2. difference between coating width on the edge of a side of the waveguide surface 3 connected to the light output surface 4 and width L2 of the second groove 63.

### DETAILED DESCRIPTION

The technical solutions of the embodiments of the present disclosure are clearly and completely described below with reference to the drawings in the embodiments of the present disclosure. Apparently, the described embodiments are merely a part rather than all of the embodiments of the present disclosure. Rather, these embodiments are provided to make the content of the present disclosure understood thoroughly and comprehensively. All other embodiments obtained by those of ordinary skill in the art based on the embodiments of the present disclosure without creative efforts should fall within the protection scope of the present disclosure.

In the description of the present disclosure, the terms such as “first”, “second” and “third” are only for the purpose of description and should not be construed as indicating or implying relative importance, or implicitly indicating a quantity of indicated technical features. Thus, features defined with “first”, “second” and “third” may explicitly or implicitly include one or more of the features. In the description of this application, unless otherwise specified, “a plurality of” means two or more.

In the description of the present disclosure, it should be noted that, unless otherwise clearly specified, meanings of terms “install”, “connected with”, and “connected to” should be understood in a broad sense. For example, the connection may be a fixed connection, a removable connection, or an integral connection; may be a mechanical connection or an electrical connection; may be a direct connection or an indirect connection by using an intermediate medium; or may be intercommunication between two components. The terms “vertical”, “horizontal”, “left”, “right”, “upper”, “lower” and similar expressions used herein are merely for the purpose of illustration, and do not indicate or imply that the referred device or element must have a specific orientation or be constructed and operated in a specific orientation, therefore these terms cannot be understood as limitation to the present disclosure. The term “and/or” used herein includes any and all combinations of one or more of the associated listed items. Those of ordinary skill in the art may understand the specific meanings of the above terms in the present disclosure based on specific situations.

In the description of the present disclosure, it should be noted that unless otherwise defined, all technical and scientific terms used herein have the same meaning as commonly understood by those skilled in the technical field of the present disclosure. The terms used in the description of the present disclosure are for the purpose of describing particular embodiments only and are not intended to be limiting of the present disclosure. Those of ordinary skill in the art should understand the specific meanings of the above terms in the present disclosure based on specific situations.

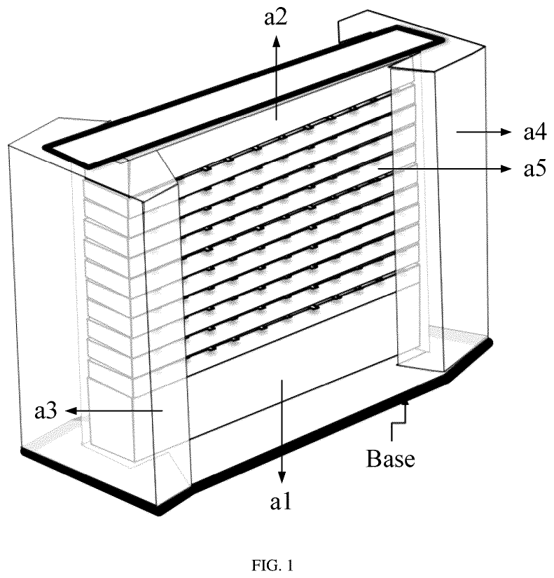

Laser diodes have been widely used in radar, medical and other technical fields due to their advantages of easy mass production and low cost. The laser diodes have a small size, and when they are stacked, the protruding laser diode will cover the adjacent laser diode to cause uneven mirror coating, thereby affecting the electrical performance of the laser diode. In view of this, in the prior art, as shown in FIG. 1, a spacer is provided between each two adjacent laser diodes to separate them. In this way, the two adjacent laser diodes are avoided from covering each other. However, the large number of spacers inside the fixture will greatly increase the product processing cost. To solve this problem, the present disclosure designs a laser diode that eliminates the spacers, greatly reducing the product processing cost. The present disclosure improves the structure of the laser diode by forming at least one groove on a bottom surface of the laser diode to facilitate coating on edges of two sides of a waveguide surface, on a light output surface, and on a reflective surface. The present disclosure achieves a desired coating effect and ensures the electrical performance of the laser diode. Specifically, embodiments of the present disclosure provide a laser diode, a laser diode bar, a method for coating a resonant mirror of a laser diode array, a method for preparing a stacked high-density laser diode array, and a fixture for fixing the laser diode bar.

### Embodiment 1

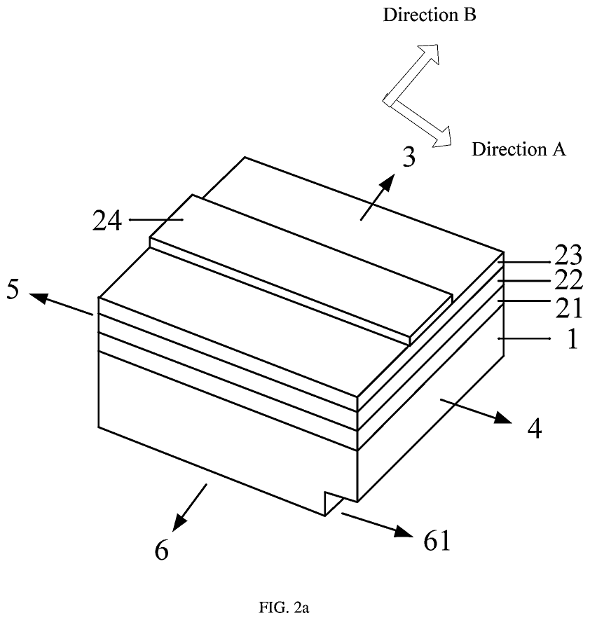

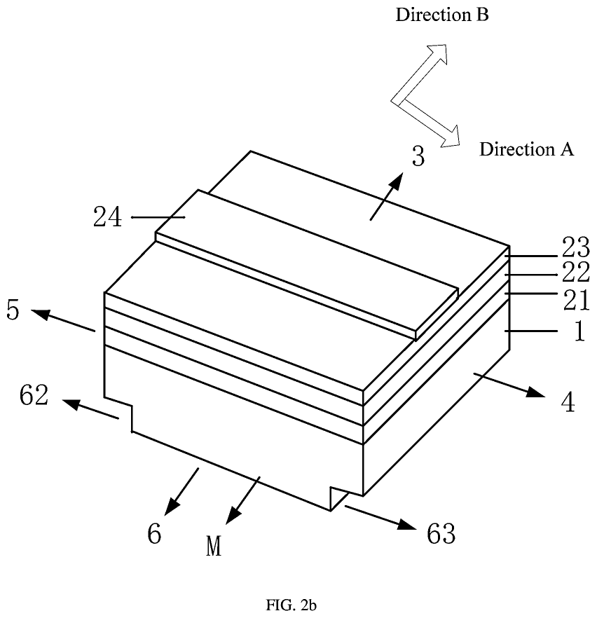

Embodiment 1 provides a laser diode. Specifically, refer to FIGS. 2a to 2b, FIG. 2a is a structural diagram of a laser diode with one groove according to Embodiment 1 of the present disclosure, and FIG. 2b is a structural diagram of a laser diode with two grooves according to Embodiment 1 of the present disclosure. In the embodiment, the laser diode includes a substrate 1 and a stack layer 2 located on the substrate. The stack layer 2 sequentially includes an N-type layer 21, an active layer 22, and a P-type layer 23 with a ridge strip 24 on a surface of the P-type layer 23 from bottom to top. The ridge strip 24 is provided on the surface of the P-shaped layer 23 along a direction A. The laser diode is provided with a waveguide surface 3, a light output surface 4, a reflective surface 5, and a bottom surface 6. It should be described that a resonant mirror of the laser diode includes the light output surface 4 and the reflective surface 5 opposite to the light output surface 4. In some literature, the light output surface 4 is also known as a front facet of the laser diode, and the reflective surface 5 is also known as a back facet of the laser diode. The facets are formed by scribing and cutting a wafer. After the facets are formed, the laser diode is coated through a facet coating technology to form a coating, thereby ensuring the performance of the laser diode. The present disclosure is described using the terms light output surface 4 and the reflective surface 5 instead of the front facet and the back facet.

A top side of the P-type layer 23 forms the waveguide surface 3, and a bottom side of the substrate 1 forms the bottom surface 6. The waveguide surface 3 is provided opposite to the bottom surface 6. The bottom surface 6 is provided with at least one groove. As shown in FIG. 2a, there is one groove, namely a groove 61. As shown in FIG. 2b, there are two grooves, namely a first groove 62 and a second groove 63. The first groove 62 is located at one end of the bottom surface 6, and the second groove 63 is located at an end of the bottom surface 6. The first groove 62 and the second groove 63 form a downwardly extending strip protrusion M on the bottom surface 6.

The groove is provided along a direction B on the bottom surface 6. The direction B is perpendicular to the direction A. The light output surface 4 and the reflective surface 5 are located at two opposite sides of the waveguide surface 3 and perpendicular to the waveguide surface 3. In the embodiment of the present disclosure, both the light output surface 4 and the reflective surface 5 are coated. In addition, due to the presence of the groove of the laser diode, edges of the two sides of the waveguide surface 3 are also coated, which will be described in detail below.

Preferably, in the above embodiment, the N-type layer 21 of the laser diode includes an N-type metal layer, and the P-type layer 23 includes a P-type metal layer.

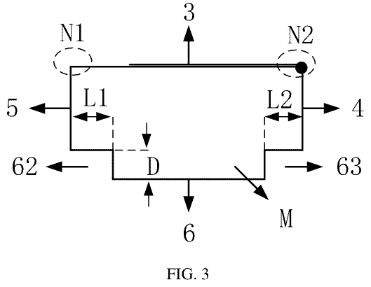

The structure of the laser diode with two grooves shown in FIG. 2b is described as follows. Refer to FIG. 3, FIG. 3 is a cross-sectional view of the laser diode with two grooves. In the figure, a top side forms the waveguide surface 3 of the laser diode (denoted by a waveguide line, which corresponds to the ridge strip formed by subsequent processing), a bottom side forms the bottom surface 6 of the laser diode, a right side forms the light output surface 4 of the laser diode, and a left side forms the reflective surface 5 of the laser diode. As shown in the figure, the first groove 62 on the left and the second groove 63 on the right form the downwardly extending strip protrusion M on the bottom surface 6, equivalent to forming cavities at left and right sides of the bottom of the laser diode. When the laser diode is coated, the light output surface 4 and the reflective surface 5 are coated. Due to the presence of the grooves, the bottom surface 6 of the laser diode will not be coated, while the edges on the two sides of the waveguide surface 3 (i.e. dashed boxes N1 and N2 in the figure), the light output surface 4, and the reflective surface 5 will all be coated.

As for the strip protrusion M, an extension height D of the strip protrusion M will affect the subsequent coating effect. In an optional implementation of this embodiment, in order to ensure the coating effect of the laser diode, the extension height D of the strip protrusion M is 0.5-20 μm, for example, 0.5 μm, 10 μm, 12 μm, 14 μm, 15 μm, etc. Of course, the extension height D of the strip protrusion can be set according to actual usage requirements, and will not be elaborated herein.

As for the first groove 62 on the left, a width L1 of the first groove 62 on the left will affect the subsequent coating effect. In an optional implementation of this embodiment, in order to ensure the coating effect of the laser diode, the width L1 of the first groove 62 on the left is 5-50 μm, for example, 5 μm, 10 am, 12 am, 14 μm, 15 am, etc. Of course, the width L1 of the first groove 62 on the left can be set according to actual usage requirements, and will not be elaborated herein.

As for the second groove 63 on the right, a width L2 of the second groove 63 on the right will affect the subsequent coating effect. In an optional implementation of this embodiment, in order to ensure the coating effect of the laser diode, the width L2 of the second groove 63 on the right is 5-50 μm, for example, 5 μm, 10 μm, 12 μm, 14 μm, 15 μm, etc. Of course, the width L2 of the second groove 63 on the right can be set according to actual usage requirements, and will not be elaborated herein.

It should be noted that the width L1 of the first groove 62 on the left and the width L2 of the second groove 63 on the right do not need to be the same. When the light output surface 4 and reflective surface 5 of the laser diode are processed, by controlling the size of the grooves, the coating can extend to the edges of the two sides of the waveguide surface 3 (i.e. the dashed boxes N1 and N2 in the figure). In addition, due to the small size of the grooves, the residue of the coating will not spread to the bottom surface 6 of the laser diode during actual processing, ensuring the coating effect of the laser diode.

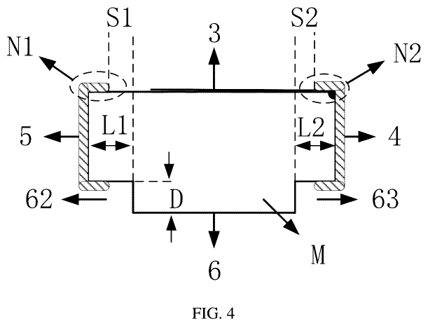

In an actual coating process, the coating on the light output surface 4 can spread to the edge of the side of the waveguide surface 3 connected to the light output surface 4, causing a portion of one end of the waveguide surface 3 to be coated. In addition, the coating on the reflective surface 5 can spread to the edge of the side of the waveguide surface 3 connected to the reflective surface 5, causing a portion of the other end of the waveguide surface 3 to be coated. Preferably, refer to FIG. 4, FIG. 4 is a cross-sectional view of a coated laser diode according to an embodiment of the present disclosure. The edge of the side of the waveguide surface 3 connected to the light output surface 4, the edge of the side of the waveguide surface 3 connected to the reflective surface 5, the light output surface 4, and the reflective surface 5 are all coated. Preferably, a difference S2 between a coating width on the edge of the side of the waveguide surface 3 connected to the light output surface 4 and the width L2 of the second groove 63 is greater than 2 μm. Furthermore, a difference S1 between a coating width on the edge of the side of the waveguide surface 3 connected to the reflective surface 5 and the width L1 of the first groove 62 is greater than 2 μm. Of course, the actual coating width can be set according to actual usage requirements, and will not be elaborated herein.

In this embodiment, the bottom surface 6 of the laser diode can be provided with one groove or two grooves. In practical applications, if there is only one groove, the groove, i.e. the second groove 63, is preferentially provided at a side close to the light output surface 4 of the bottom surface 6. Correspondingly, the difference S2 between the coating width on the edge of the side of the waveguide surface 3 connected to the light output surface 4 and the width L2 of the second groove 63 is greater than 2 μm.

### Embodiment 2

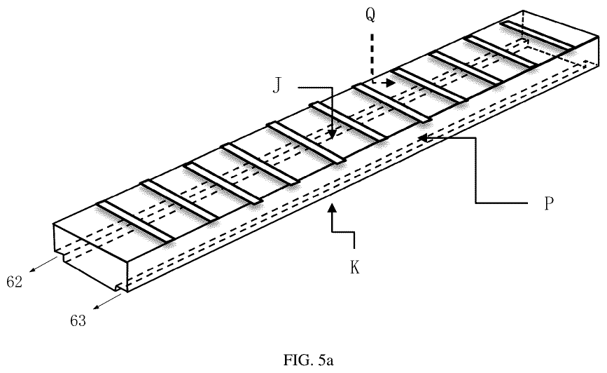

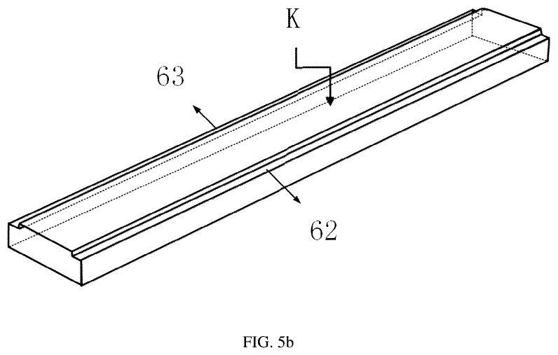

Embodiment 2 provides an uncut laser diode bar. Specifically, refer to FIGS. 5a and 5b, FIG. 5a is a structural diagram of the laser diode bar according to Embodiment 2 of the present disclosure, and FIG. 5b is a structural diagram of a bottom surface of the laser diode bar according to Embodiment 2 of the present disclosure (the laser diode bar is flipped over). As shown in the figure, in Embodiment 2, the laser diode bar includes at least two laser diodes. Each of the laser diodes is in contact with at least one other laser diode. The waveguide surface 3 of each of the laser diodes is oriented in a same direction and located in a same plane to form a first electrode surface J of the laser diode bar. The bottom surface 6 of each of the laser diodes is oriented in a same direction and located in a same plane to form a second electrode surface K of the laser diode bar. The light output surface 4 of each of the laser diodes is oriented in a same direction and located in a same plane to form a first resonant mirror P of the laser diode bar. The reflective surface 5 of each of the laser diodes is oriented in a same direction and located in a same plane to form a second resonant mirror Q of the laser diode bar.

In this embodiment, the laser diode bar is usually made of a semiconductor material such as GaAs, AlGaAs, and InP, which is not specifically limited herein. In addition, in this embodiment, the laser diode bar is a rectangular strip, and its bottom surface is provided with the groove as described above, which will not be repeated herein.

### Embodiment 3

Embodiment 3 provides a method for coating a resonant mirror of a laser diode array, suitable for the laser diode bar as described above. The method for coating a resonant mirror of a laser diode array includes the following steps.

At least two laser diodes are arranged to form a laser diode bar. The waveguide surface of each of the laser diodes is oriented in the same direction and located in the same plane, the bottom surface of each of the laser diodes is oriented in the same direction and located in the same plane, the light output surface of each of the laser diodes is oriented in the same direction and located in the same plane, and the reflective surface of each of the laser diodes is oriented in the same direction and located in the same plane.

Laser diode bars are stacked to form a laser diode array. Each of the laser diode bars is in contact with at least one other laser diode bar. The light output surface of each of the laser diodes in each of the laser diode bars is oriented in the same direction, and the reflective surface of each of the laser diodes in each of the laser diode bars is oriented in the same direction.

In other words, the first resonant mirror P of each of the laser diode bars is oriented in the same direction, and the second electrode surface K of each of the laser diode bars is oriented in the same direction. That is to say, the second electrode surface K of each of the laser diode bars is oriented downwards, the first electrode surface J of each of the laser diode bars is oriented upwards, the first resonant mirror P of each of the laser diode bars is oriented towards the same side, and the second resonant mirror Q of each of the laser diode bars is oriented towards the same other side. The design facilitates the subsequent coating process.

An anti-reflective coating is coated on the first resonant mirror P of the stacked laser diode bars, and a reflective coating is coated on the second resonant mirror Q of the stacked laser diode bars. Due to the presence of the grooves, there is a cavity between each two adjacent laser diode bars. The cavity enables the coating to extend to the first electrode surface J, which means that the edges of the two sides of the waveguide surface 3 of each of the laser diodes are coated. Meanwhile, since it is hard for the coating material to penetrate the cavity, the residue of the coating will not spread to the second electrode surface K of the laser diode bar. That is to say, the bottom surface 6 of each of the laser diodes is not coated, thereby ensuring the coating effect of the entire laser diode bar.

### Embodiment 4

The processing of the groove structure can be performed on a wafer or before a wafer process. Specifically, Embodiment 4 provides a method for preparing a stacked high-density laser diode array, including the following steps.

(1) An epitaxial layer is formed on a semiconductor chip, where the epitaxial layer includes a quantum well. It should be noted that a wafer processing technology for producing laser diodes is the same as the prior art. The epitaxial layer on a substrate includes a multi-layer n-doped material, a p-doped material, and an undoped material. The quantum well is formed within these layers and will not be elaborated herein.

(2) A first metallized layer is deposited on a first surface of the semiconductor chip, and a second metallized layer is deposited on a second surface of the semiconductor chip opposite to the first surface. A thickness of the first metallized layer and the second metallized layer is preferably 3 μm, and the metallized layer can be made of titanium, titanium tungsten, platinum, gold or other suitable metals.

(3) A solder layer is applied on the first metallized layer.

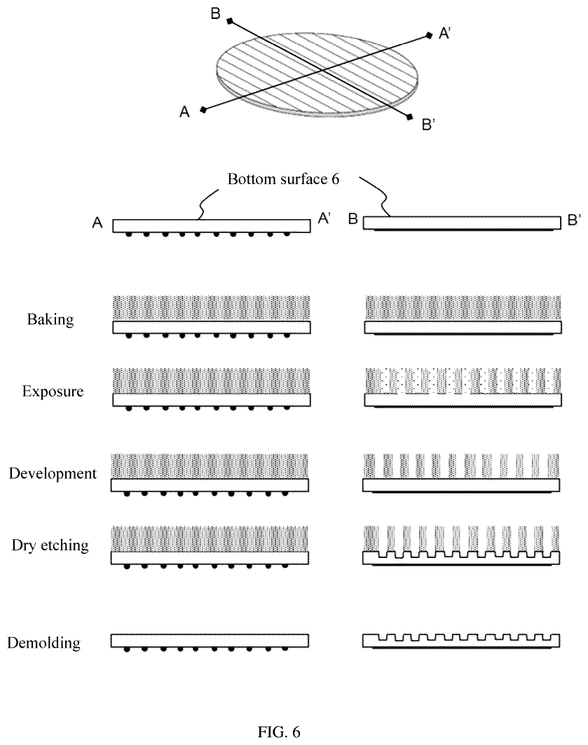

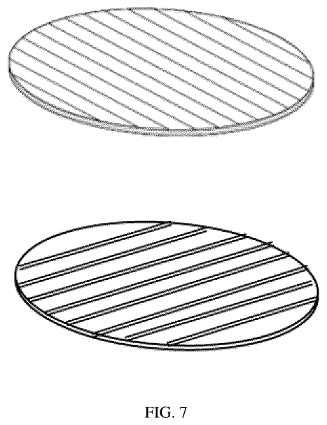

(4) An anti-corrosion agent coating is applied on the second metallized layer, and baking, exposure, development, dry etching, and demolding are performed in sequence to form multiple grooves on the second surface of the semiconductor chip. Specifically, refer to FIG. 6, FIG. 6 is a flowchart and cross-sectional view of processing the semiconductor chip to form the grooves. It should be noted that since the groove is located on the bottom surface of the laser diode, in order to facilitate processing and display, the semiconductor chip is flipped over in FIG. 6. That is to say, in the cross-sectional view of FIG. 6, a top side indicates the bottom surface 6 of the laser diode, while a bottom side indicates the waveguide surface 3 of the laser diode. In addition, in FIG. 6, the left and right figures show the semiconductor chip at different angles during processing. In the right figure, the ridge strips of the semiconductor chip are in a B→B′ direction. In the left figure, the ridge strips of the semiconductor chip are in an A→A′ direction. After the processing, a semiconductor chip to be cut is formed. Specifically, refer to FIG. 7, FIG. 7 is a schematic diagram of a processed semiconductor chip. In FIG. 7, the upper figure shows the processed semiconductor chip with the waveguide surface oriented upwards in Embodiment 5, and the lower figure shows the processed semiconductor chip with the bottom surface oriented upwards in Embodiment 5.

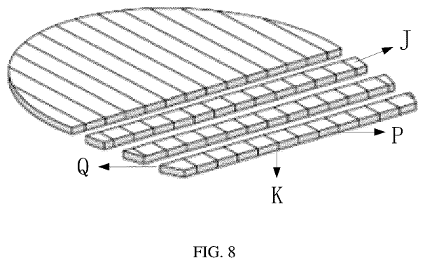

(5) Specifically, refer to FIG. 8, FIG. 8 is a schematic diagram of cutting the semiconductor chip. The semiconductor chip is cut into multiple laser diode bars.

(6) The multiple laser diode bars are stacked to form the laser diode array. The waveguide surface of each of the laser diodes in each of the laser diode bars is oriented in a same direction and located in a same plane. The bottom surface of each of the laser diodes in each of the laser diode bars is oriented in a same direction, located in a same plane, and provided with at least one groove. The light output surface of each of the laser diodes in each of the laser diode bars is oriented in a same direction and located in a same plane. The reflective surface of each of the laser diodes in each of the laser diode bars is oriented in a same direction and located in a same plane.

In other words, each of the laser diode bars is provided with a first electrode surface J, and the first electrode surface is provided with a strip solder layer. Each of the laser diode bars is provided with a first resonant mirror P and a second resonant mirror Q. The first resonant mirror P and the second resonant mirror Q are perpendicular to the first electrode surface J. Each of the laser diode bars is provided with a second electrode surface K, and the second electrode surface K is provided with at least one groove (the groove is not shown in the figure due to a size limitation).

(7) The laser diode array is put into a vacuum chamber for vacuum sputtering. Thus, an anti-reflective coating is applied on the light output surface of each of the laser diodes in the laser diode bars, and a reflective coating is applied on the reflective surface of each of the laser diodes in the laser diode bars. A coating is applied on the edge of the side of the waveguide surface connected to the light output surface of each of the laser diodes in the laser diode bars. A coating is applied on the edge of the side of the waveguide surface connected to the reflective surface of each of the laser diodes in the laser diode bars.

The first resonant mirror P of the laser diode bar is applied with an anti-reflective coating, and the second resonant mirror Q of the laser diode bar is applied with a reflective coating. Through the groove structure, during the coating of the laser diode, the coating on the light output surface can spread to the edge of the side of the waveguide surface connected to the light output surface, such that a portion of one end of the waveguide surface is coated. In addition, through the groove structure, during the coating of the laser diode, the coating on the reflective surface can spread to the edge of the side of the waveguide surface connected to the reflective surface, such that a portion of the other end of the waveguide surface is coated.

Preferably, after coating, the multiple laser diode bars stacked can further be subjected to vacuum reflow soldering, so as to form the stacked high-density laser diode array.

### Embodiment 5

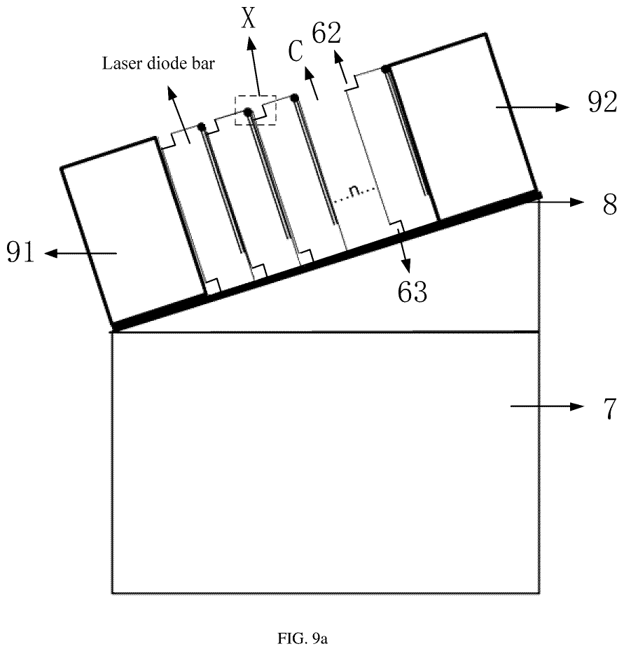

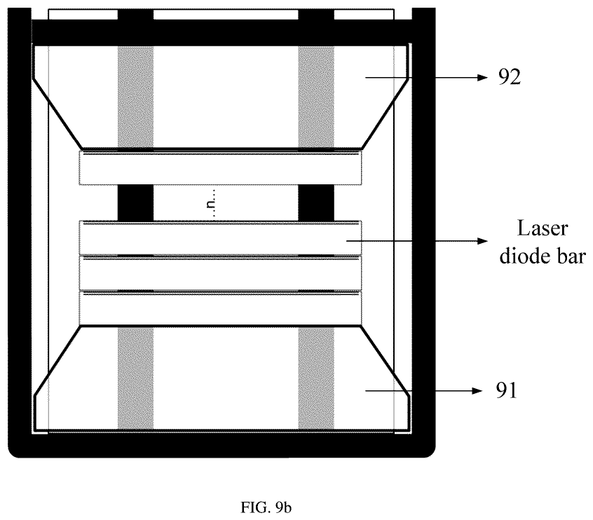

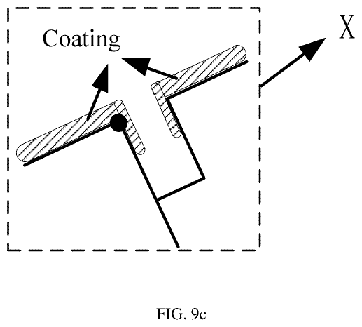

Embodiment 5 provides a fixture for fixing a laser diode bar, suitable for the laser diode bar as described above. Specifically, refer to FIGS. 9a to 9c. FIG. 9a is a side sectional view of the fixture for fixing a laser diode bar according to Embodiment 5 of the present disclosure, FIG. 9b is a top view of the fixture for fixing a laser diode bar according to Embodiment 5 of the present disclosure, and FIG. 9c is an enlarged view of X of the fixture for fixing a laser diode bar according to Embodiment 5 of the present disclosure. The fixture for fixing a laser diode bar includes a base 7 and a stage 8.

A top surface of the base 7 is preferably an inclined surface. The inclined surface enables a device to be processed which is placed on the top surface to be clamped and fixed due to its own gravity, thereby facilitating assembly and subsequent coating. In addition, the top surface of base 7 can also be a flat surface. The form of the top surface of the base is determined by the actual processing and design requirements, and will not be elaborated herein.

The stage 8 is provided on the top surface of the base 7. Two ends of the stage 8 are provided with stops, and the stops extend in a direction away from the inclined surface. In this embodiment, a left end of the stage 8 is provided with a first stop 91, and a right end of stage 8 is provided with a second stop 92. The first stop 91 and the second stop 92 form an open holding space C on the stage 8. Multiple laser diode bars are arranged sequentially along their width direction in the holding space C. The groove of each of the laser diodes of the laser diode bar (in this embodiment, there is one groove, i.e. the groove 61 shown in the figure) is oriented in a same direction.

Preferably, cross sections of the first stop 91 and the second stop 92 are trapezoidal or in other shapes, which is determined by those skilled in the art based on the actual needs of the product.

If there are too many laser diode bars loaded, it will be difficult to ensure linear processing due to the influence of gravity or vibration on the inclined surface. Therefore, the fixture for fixing a laser diode bar further includes multiple support bars.

The support bars are preferably fixed to the stage 8, and are parallel to the laser diode bars in the holding space C. The fixed support bars ensure the stability of all the laser diode bars, thereby ensuring linear processing. Of course, the support bars can also be detachably provided on the stage. For example, the positions of the support bars are first adjusted to suitable positions on the stage, and then the support bars are fixed, making it easy for processing personnel to pick up the laser diode bars. It should be noted that the materials of the stops and the support bars are determined based on actual product design requirements, and can be mono-metal, plastic, or alloy, etc.

Preferably, a length of the support bar is determined based on actual fixture design requirements, and will not be specifically limited herein. Specifically, refer to FIGS. 10a and 10b, FIG. 10a is a partial cross-sectional view of the fixture with the support bars according to Embodiment 5 of the present disclosure, and FIG. 10b is a partial top view of the fixture with the support bars according to Embodiment 5 of the present disclosure. The introduction of the support bars further ensures the stability of all the laser diode bars on the stage.

The laser diode, the laser diode bar, the method for coating the resonant mirror of the laser diode array, and the method for preparing the stacked high-density laser diode array provided by the embodiments of the present disclosure achieve most if not all of the following beneficial effects.

The structure of the laser diode is improved by forming at least one groove on the bottom surface of the laser diode. Through the groove, when the laser diode is coated, the coating on the light output surface can spread to the edge of the side of the waveguide surface connected to the light output surface, such that a portion of one end of the waveguide surface is coated. In addition, through the groove, when the laser diode is coated, the coating on the reflective surface can spread to the edge of the side of the waveguide surface connected to the reflective surface, such that a portion of the other end of the waveguide surface is coated. Finally, parts of the formed laser diode product, including the light output surface, the reflective surface, and a portion of the waveguide surface are all coated. Therefore, it is easy to coat the edges of the two sides of the waveguide surface, the light output surface, and the reflective surface, thereby ensuring the electrical performance of the laser diode.

The above embodiments merely represent several embodiments of the present disclosure, and the descriptions thereof are specific and detailed, but they should not be construed as limiting the patent scope of the present disclosure. It should be noted that those of ordinary skill in the art can further make several variations and improvements without departing from the concept of the present disclosure, and all of these fall within the protection scope of the present disclosure. Therefore, the protection scope of the present disclosure shall be subject to the protection scope defined by the claims.

1. A laser diode, comprising a substrate and a stack layer located on the substrate, wherein the stack layer comprises an N-type layer, an active layer, and a P-type layer with a ridge strip on a surface of the P-type layer; and the laser diode is provided with a waveguide surface, a light output surface, a reflective surface, and a bottom surface;
a top side of the P-type layer forms the waveguide surface, and a bottom side of the substrate forms the bottom surface; and the waveguide surface is provided opposite to the bottom surface;
the bottom surface is provided with at least one groove; and an extension direction of the groove is perpendicular to the ridge strip;
the light output surface and the reflective surface are located at two opposite sides of the waveguide surface and perpendicular to the waveguide surface; and
an edge of a side of the waveguide surface connected to the light output surface, an edge of a side of the waveguide surface connected to the reflective surface, the light output surface, and the reflective surface are all coated.

2. The laser diode according to claim 1, wherein the bottom surface is provided with a first groove and a second groove; the first groove is located at an end of the bottom surface connected to the reflective surface; the second groove is located at an end of the bottom surface connected to the light output surface; and the first groove and the second groove form a downwardly extending strip protrusion on the bottom surface.

3. The laser diode according to claim 2, wherein the strip protrusion has a height of 0.5-20 μm.

4. The laser diode according to claim 2, wherein the first groove has a width of 5-50 μm, and the second groove has a width of 5-50 μm.

5. The laser diode according to claim 2, wherein a difference between a coating width on the edge of the side of the waveguide surface connected to the light output surface and the width of the second groove is greater than 2 μm.

6. A method for coating a resonant mirror of a laser diode array, suitable for the laser diode according to claim 1, and comprising the following steps:
arranging at least two laser diodes to form a laser diode bar, wherein the waveguide surface of each of the laser diodes is oriented in a same direction and located in a same plane, the bottom surface of each of the laser diodes is oriented in a same direction and located in a same plane, the light output surface of each of the laser diodes is oriented in a same direction and located in a same plane, and the reflective surface of each of the laser diodes is oriented in a same direction and located in a same plane;
stacking at least two laser diode bars to form a laser diode array, wherein each of the laser diode bars is in contact with at least one other laser diode bar; the light output surface of each of the laser diodes in each of the laser diode bars is oriented in a same direction and located in a same plane, and the reflective surface of each of the laser diodes in each of the laser diode bars is oriented in a same direction and located in a same plane; and
applying an anti-reflective coating on the light output surface of each of the laser diodes in each of the laser diode bars stacked; applying a reflective coating on the reflective surface of each of the laser diodes in each of the laser diode bars stacked; applying a coating on the edge of the side of the waveguide surface connected to the light output surface of each of the laser diodes in each of the laser diode bars stacked; and applying a coating on the edge of the side of the waveguide surface connected to the reflective surface of each of the laser diodes in each of the laser diode bars stacked.

7. A method for preparing a stacked high-density laser diode array, wherein the laser diode array is formed by stacking laser diode bars; each of the laser diode bars comprises at least two laser diodes according to claim 1; and the method for preparing a stacked high-density laser diode array comprises the following steps:
forming an epitaxial layer on a semiconductor chip, wherein the epitaxial layer comprises a quantum well;
depositing a first metallized layer on a first surface of the semiconductor chip, and depositing a second metallized layer on a second surface of the semiconductor chip opposite to the first surface;
applying a solder layer on the first metallized layer;
applying an anti-corrosion agent coating on the second metallized layer, and performing baking, exposure, development, dry etching, and demolding in sequence to form multiple grooves on the second surface of the semiconductor chip;
cutting the semiconductor chip into multiple laser diode bars;
stacking the multiple laser diode bars to form the laser diode array, wherein the waveguide surface of each of the laser diodes in each of the laser diode bars is oriented in a same direction and located in a same plane; the bottom surface of each of the laser diodes in each of the laser diode bars is oriented in a same direction, located in a same plane, and provided with at least one groove; the light output surface of each of the laser diodes in each of the laser diode bars is oriented in a same direction and located in a same plane; and the reflective surface of each of the laser diodes in each of the laser diode bars is oriented in a same direction and located in a same plane; and
putting the laser diode array into a vacuum chamber for vacuum sputtering, such that an anti-reflective coating is applied on the light output surface of each of the laser diodes in each of the laser diode bars, a reflective coating is applied on the reflective surface of each of the laser diodes in each of the laser diode bars, a coating is applied on the edge of the side of the waveguide surface connected to the light output surface of each of the laser diodes in each of the laser diode bars, and a coating is applied on the edge of the side of the waveguide surface connected to the reflective surface of each of the laser diodes in each of the laser diode bars.
